(19) United States
(12) Patent Application Publication
(10) Pub. No.: US 2026/0318524 A1
(43) Pub. Date: Oct. 15, 2026

(54) Secure thermal contact PCBA to housing by using curved surfaces

(71) Applicant: SIGNIFY HOLDING B.V., EINDHOVEN (NL)

(72) Inventors: PETRUS JOHANNES MARIA VAN OS, HEESWIJK (NL); RONNY CHRISTIANUS HENDRIKUS VAN HOEK, EINDHOVEN (NL); MICHAL PIOTR PANKAU, EINDHOVEN (NL)

(21) Appl. No.: 19/483,052

(22) PCT Filed: Apr. 23, 2024
(86) PCT No.: PCT/EP2024/061051

§ 371 Date: Nov. 10, 2025

(30) Foreign Application Priority Data
May 16, 2023 (EP) 23173667.9

(51) Int. Cl. F21V 29/508; F21V 23/00; F21V 29/70

(52) U.S. Cl. CPC F21V 29/508; F21V 23/009; F21V 29/70

(57) ABSTRACT

The invention provides a light generating system (1000) comprising an arrangement (2000), wherein the arrangement (2000) comprises an electrical arrangement (500), a housing (560), and a thermal conduction arrangement (600), wherein the thermal conduction arrangement comprises a curved surface exerting a force on part of the electrical arrangement.

### FIELD OF THE INVENTION

The invention relates to a light generating system comprising a thermal conduction arrangement. The invention further relates to a lighting device comprising the light generating system.

### BACKGROUND OF THE INVENTION

The use of heat conducting elements are known in the art. For instance, US2002154487A1 describes a radio frequency module of an audio appliance, in particular of a car radio, which has at least one electrical component which produces heat loss and has optimum heat dissipation. The electrical component producing heat loss is mounted on a printed circuit board arranged inside a metal housing designed to be a radio frequency shield. The invention provides for an inner surface of the housing to have a heat conducting element which extends from the housing to the component and produces a thermally conductive connection between the component and the housing.

### SUMMARY OF THE INVENTION

Light generating systems may comprise or may be accompanied by electronic arrangements, for example drivers, to power and/or control the light generating systems. Electrical components comprised by these electronic arrangements may generate heat over the course of their operation. Operating such electrical components at high temperatures may reduce the lifespan of the electronic arrangement and may also affect its performance. Hence, it is desired to provide thermal management for such electrical components. To this end, thermal potting materials (that are typically applied to arrangements in liquid form prior to curing into solid form, e.g. silicone-based materials with thermal conductive fillers or asphalt-based materials) and thermal interface materials (that are typically applied to arrangements in solid form, e.g. gap fillers) may be used to cool electrical components by guiding away heat. Such materials may typically have high thermal conductivity and may e.g. comprise epoxy, polyurethane, and/or a silicone compound. However, it may be challenging to remove potting materials and thermal interface materials as they may adhere to the electrical components. Therefore, these compounds and/or the (useful) electrical components may not be sustainable nor recyclable. Another cooling solution for electrical components may be thermal conductive pads. However, thermal conductive pads may be non-recyclable, heavy, and expensive. Further, due to the thermal expansion of thermal potting materials, thermal interface materials, and thermal conductive pads, electrical components may face a reduction in lifespan and/or performance because of shrink and/or expansion stresses. Alternatively, heat sinks are commonly used to dissipate heat.

In high power drivers, even more heat is generated and therefore it is even more important to provide good heat dissipation. For example, newly developed drivers for stadium lighting have high power output (such as up to 1800 W). Cooling of such drivers becomes more difficult, especially cooling relatively small components with high power losses. In high power drivers, often extra large heat sinks are used for cooling and/or to make thermal contact often gap pads or thermal grease is used. Using extra heat sinks and thermal interface materials is complex and expensive.

It appears particularly desirable to provide a (more) sustainable cooling solution for light generating systems. Hence, it is an aspect of the invention to provide an alternative light generating system, which preferably further at least partly obviates one or more of above-described drawbacks. The present invention may have as object to overcome or ameliorate at least one of the disadvantages of the prior art, or to provide a useful alternative.

According to a first aspect, the invention provides a system comprising an arrangement. In embodiments, the system may especially comprise a light generating system. Embodiments of the system are herein especially described in relation to the light generating system, however the embodiments may also apply to other systems. The arrangement may in embodiments comprise an electrical arrangement, a housing, and a thermal conduction arrangement. In embodiments, the housing may comprise a housing bottom. In further embodiments, the housing bottom may comprise an interior bottom face and one or more (housing) walls. The electrical arrangement may in embodiments be configured in the housing. In embodiments, the electrical arrangement may comprise a support and a plurality of electrical components supported by the support. The support may in embodiments comprise a first face and a second face. The support may in further embodiments comprise a support cross-sectional plane. The support cross-sectional plane may in embodiments be configured parallel to the first face (and the second face). The support may in further embodiments comprise a support cross-sectional area As. The support may in further embodiments comprise a largest dimension (L₁) in the support cross-sectional plane. In embodiments, the support may be arranged at a distance (h1) from the housing bottom. The first face may in embodiments comprise a primary first face part. Especially at least a first electrical component may in embodiments be mechanically and/or electrically coupled to the primary first face part. The second face may in embodiments comprise a primary second face part. The primary second face part may in embodiments be configured opposite of the primary first face part. The thermal conduction arrangement may in embodiments comprise a first thermal conduction arrangement part. The first thermal conduction arrangement part may in embodiments be configured in thermal contact with the housing bottom. In alternative embodiments, the first thermal conduction arrangement part may at least partly be comprised by the housing bottom. The first thermal conduction arrangement part may in embodiments comprise a first top face. The first top face may in embodiments be configured in thermal contact with the primary second face part. In embodiments, the first top face may have an overlap area A_{O1}, wherein the overlap area Aoi may be defined as an area of overlapping parts of projections of the first top face and the second face on the housing bottom. In embodiments, 0.05≤A_{O1}/Aₛ≤0.33. In embodiments, the first top face may comprise a first curvature with a first curvature radius (r₁). Especially, in embodiments r₁≥0.5*L₁. The first curvature may in embodiments exert a force on the primary second face part in a direction away from the housing bottom. Additionally or alternatively, the thermal conduction arrangement may in embodiments comprise a second thermal conduction arrangement part. The second thermal conduction arrangement part may in embodiments comprise a second bottom face configured in thermal contact with the primary first face part. The second bottom face may in embodiments comprise a second curvature with a second curvature radius (r₂). In embodiments r₂>0.5*L₁. The second curvature may in embodiments locally exert a force on the primary first face part in a direction of the first top face. Hence, in a first aspect, the invention provides a (light generating) system comprising an arrangement, wherein the arrangement comprises an electrical arrangement, a housing, and a thermal conduction arrangement, wherein: the housing comprises a housing bottom; the electrical arrangement, configured in the housing, comprises a support and a plurality of electrical components supported by the support; the support comprises a first face, a second face, a support cross-sectional plane configured parallel to the first face, a support cross-sectional area Aₛ, and a largest dimension (L₁) in the support cross-sectional plane; wherein the support is arranged at a distance (h1) from the housing bottom; wherein the first face comprises a primary first face part, wherein at least a first electrical component is mechanically and/or electrically coupled to the primary first face part; wherein the second face comprises a primary second face part, configured opposite of the primary first face part; the thermal conduction arrangement comprises a first thermal conduction arrangement part, configured in thermal contact with the housing bottom or at least partly comprised by the housing bottom; wherein the first thermal conduction arrangement part comprises a first top face configured in thermal contact with the primary second face part; wherein the first top face has an overlap area Aoi, defined as an area of overlapping parts of projections of the first top face and the second face on the housing bottom, wherein 0.05≤A_{O1}/Aₛ≤0.33; and wherein one or more of the following applies: (i) the first top face comprises a first curvature with a first curvature radius (r₁), wherein r₁≥0.5*L₁; wherein the first curvature exerts a force on the primary second face part in a direction away from the housing bottom; and (ii) the thermal conduction arrangement comprises a second thermal conduction arrangement part, wherein the second thermal conduction arrangement part comprises a second bottom face configured in thermal contact with the primary first face part; wherein the second bottom face comprises a second curvature with a second curvature radius (r₂), wherein r₂≥0.5*L₁; wherein the second curvature locally exerts a force on the primary first face part in a direction of the first top face.

With such (light generating) system, good heat dissipation may be achieved with no need for extra (large) heat sinks or thermal interphase material.

As indicated above, the (light generating) system may comprise an arrangement, wherein the arrangement may in embodiments comprise an electrical arrangement, a housing, and a thermal conduction arrangement. Below, these components are described in more detail.

The housing may in embodiments especially comprise a housing bottom. In further embodiments, the housing may comprise one or more housing walls. The housing bottom and the one or more housing walls may especially form the housing. The housing may in embodiments comprise the electrical arrangement. In further embodiments, the housing may comprise the thermal conduction arrangement. The housing may in embodiments at least partly enclose the electrical arrangement and the thermal conduction arrangement. Especially, the housing may in embodiments (essentially) entirely enclose the electrical arrangement and the thermal conduction arrangement. The housing may in specific embodiments comprise a covering, such as a lid. The covering may be configured to allow opening and closing of the housing such that the interior of the housing may be accessed. A housing wall may comprise the covering. In certain embodiments, the covering may (essentially) comprise a housing wall. The housing and the covering may be attached to each other and/or sealed, to provide an essentially closed interior (hosting the electrical arrangement).

Note that terms like “top” and “bottom” do not limit the application. The (electronic) arrangement and system may be used in essentially any position, including “upside-down” configurations of the top and the bottom.

The electrical arrangement may in embodiments especially be configured in the housing. The electrical arrangement may in embodiments comprise a support and a plurality of electrical components supported by the support. In embodiments, the electrical arrangement may be or may comprise a printed circuit board (PCB).

The support may comprise a first face and a second face. In embodiments, the first face may be configured parallel to the second face. The support may further comprise a support cross-sectional plane configured parallel to the first face. Especially, the support cross-sectional plane passes through the support between the first face and the second face. In embodiments wherein the first face is configured parallel to the second face, the support cross-sectional plane may (also) be configured parallel to the second face. The support may further comprise a support cross-sectional area Aₛ. The support cross-sectional area Aₛ may especially be defined as an area of a projection of the support on the support cross-sectional plane. The support may have a largest dimension (L₁) in the support cross-sectional plane. The largest dimension (L₁) may be a diameter or diagonal of the support cross-sectional plane. The support may be arranged (substantially) parallel to the housing bottom. The support may in embodiments be arranged at a distance (h1) from the housing bottom. In embodiments, the distance (h1) may be defined as a shortest distance between the support (at a position of the secondary (support) part as defined below) and the housing bottom. In embodiments, the largest dimension (L₁) may be selected from the range of 4-120 cm, such as selected from the range of 10-80 cm, like in embodiments up to about 50 cm.

In embodiments, the support may comprise a primary (support) part. In such embodiments, the first face may especially comprise a primary first face part. Similarly, the second face may in such embodiments especially comprise a primary second face part. Especially, the primary (support) part may comprise the primary first face part and the primary second face part. In embodiments, the primary second face part may be configured opposite of the primary first face part. Especially, “opposite” may herein refer to the primary second face part and the primary first face part to be configured on different sides of the support cross-sectional plane. In embodiments, at least a first electrical component may be functionally connected to the primary first face part. Especially, the first electrical component may generate heat during operation. In embodiments, a plurality of (other) electrical components may be functionally connected to a secondary first face part. The term “functionally connected” may herein especially refer to one or more of mechanically connected, electrically connected, thermally connected, and attached. Thus, in embodiments, the first electrical component may be mechanically and/or electrically connected to the primary first face part. Similarly, in embodiments, the plurality of (other) electrical components may be mechanically and/or electrically connected to a secondary first face part. Hence, the first face may in embodiments essentially consist of the primary first face part and the secondary first face part.

Especially, the electrical components are mechanically and electrically coupled to the support, more especially to the first face. Especially, “mechanically coupled” may refer to a mechanical connection and “electrically coupled” may refer to an electrically conductive connection. Herein, the term “functionally coupled” may in embodiments refer to a physical connection or mechanical connection between at least two elements, such as via one or more of a screw, a solder, an adhesive, a melt connection, a click connection, etc. The terms “physical connection” and “mechanical connection” may herein interchangeably be used. The terms “physical connection” and “mechanical connection” may thus also refer to an adhesive connection. Alternatively or additionally, the term “functionally coupled” may in embodiments refer to an electrically conductive connection between at least two connections. When two (or more) elements have an electrically conductive connection, then there may be a conductivity (at room temperature) between the two (or more) elements of at least 1.10⁵ S/m, such as at least 1.10⁶ S/m. In general, an electrically conductive connection will be between two (or more) elements each comprising an electrically conductive material, which may be in physical contact with each other or between which an electrically conductive material is configured. Herein a conductivity of an insulated material may especially be equal to or smaller than 1·10⁻¹⁰ S/m, especially equal to or smaller than 1·10⁻¹³ S/m. Herein a ratio of an electrical conductivity of an isolating material (insulator) and an electrical conductivity of an electrically conductive material (conductor) may especially be selected smaller than 1·10⁻¹⁵.

As indicated above, the support may comprise a primary (support) part. In further embodiments, the support may comprise a secondary (support) part. The secondary (support) part may especially comprise part of the support that is not comprised by the primary (support) part.

The thermal conduction arrangement may in embodiments comprise a first thermal conduction arrangement part. The first thermal conduction arrangement part may in embodiments especially be configured in thermal contact with the housing bottom. Additionally or alternatively, the first thermal conduction arrangement part may in embodiments be at least partly comprised by the housing bottom. The first thermal conduction arrangement part may in embodiments comprise a first (thermal conduction arrangement) top face. Especially, the first top face may in embodiments be configured in thermal contact with the primary second face part. The first top face may have an overlap area A_{O1}, defined as an area of overlapping parts of projections of the first top face and the second face on the housing bottom. In embodiments 0.02≤A_{O1}/Aₛ≤0.5, especially 0.05≤A_{O1}/Aₛ≤0.33, such as 0.1≤A_{O1}/Aₛ≤0.25. Thus, the first thermal conduction arrangement part may provide a local (additional) thermal contact. An area of (physical) contact between the first top face and the second face, which may be indicated as first contact area A_{C1}, when projected on the housing bottom, may in embodiments thus be at maximum the area of overlap area A_{O1}.

Hence, the second face may comprise a total second face area, of which part, indicated as “primary second face part”, may be opposite of the primary first face part comprising the first electrical component, and which primary second face part may be bent by the first thermal conduction arrangement part. The total second face area may essentially be A_{S}. This first thermal conduction arrangement part may be in contact with part of the primary second face part; this part of the primary second face part in contact with the second thermal conduction arrangement part may have an area, indicated as contact area (A_{C1}). The area of the primary second face part is indicated as area A₅₁₂₁. Therefore, in embodiments A_{C1}≤A5121<A_{S}. See further also below.

In embodiments, the first top face may comprise a first curvature with a first curvature radius (r₁). In embodiments r₁≥0.3*L₁, such as r₁≥0.5*L₁, especially r₁≥0.6*L₁. Especially, the first curvature may provide the first thermal conduction arrangement with a concave shape. Especially, the first curvature may in embodiments exert a force on the primary second face part in a direction away from the housing bottom. More especially, the exerted force may force the first top face against the primary second face part. In this way, the primary second face part may be configured in good contact with the first top face.

Hence, heat generated by the first electrical component may be dissipated very well to the thermal conduction arrangement.

Additionally or alternatively, the thermal conduction arrangement may in embodiments comprise a second thermal conduction arrangement part. The second thermal conduction arrangement part may in embodiments comprise a second (thermal conduction arrangement) bottom face configured in thermal contact with the primary first face part. In embodiments, the second bottom face may comprise a second curvature with a second curvature radius (r₂). In embodiments r₂≥0.3*L₁ such as r₂≥0.5*L₁, especially r₂≥0.6*L₁. The second bottom face may in embodiments have a curvature in an opposite direction to the first top face curvature direction. Especially, the second curvature may in embodiments locally exert a force on the primary first face part in a direction of the first top face and/or housing bottom. In this way, the primary second face part is configured in good contact with the first top face. Hence, heat generated by the first electrical component may be dissipated very well to the thermal conduction arrangement.

Such arrangement may especially provide an electrical arrangement (comprising a PCB) with increased contact to the (aluminum) housing by means of tension, so that the housing better acts as cooling means, and no extra heat sinks or thermal interphase material would be needed. Good thermal contact is provided by making the contact surface curved. Next, embodiments in relation to the electrical components are described.

The electrical arrangement may in embodiments comprises n electrical components supported by the support. The electrical components may in embodiments comprise one or more of transistors, resistors, inductors, capacitors, diodes, microchips, and coils. Especially, such electrical components may produce heat. In embodiments, n≥8, such as n≥10, especially n≥20. During operation of the (light generating) system one or more of the n electrical components may in embodiments at least partly rise in temperature. Especially, at least one of the 30% largest in temperature rising electrical components may in embodiments be supported by the primary first face part. In embodiments, the at least one of the 30% largest in temperature rising electrical components may be selected from the group of a field-effect transistor (FET), a diode, and a coil (or transformers). Additionally or alternatively, the at least one of the 30% largest in temperature rising electrical components may in embodiments be a surface-mount device (SMD). Especially, the at least one of the 30% largest in temperature rising electrical components may be selected from the group of an SMD field-effect transistor (SMD-FET), an SMD diode, and an SMD coil. The term “the 30% largest in temperature rising electrical components” may especially refer to the electrical components that belong to a subset of the n electrical components comprising approximately 0.3*n components having the largest (absolute) increase in temperature of the n electrical components. In further embodiments, at least 50%, such as at least 80%, especially at least 90% of the electrical components configured on the primary first face part of the support may be surface-mount devices. As will be known to a person skilled in the art, such surface-mount device (SMD) may be mounted on the first face of the support and not protrude from (the second face of) the support. This may be in contrast to traditional electrical components that protrude from the support. By using such surface-mount device(s) on the primary (support) part, the primary second face may be smooth and may have a large contact area with the first thermal conduction arrangement for optimal heat dissipation. In further embodiments at least 50% of all electrical components may be mechanically and/or electrically coupled to the secondary first face part. In embodiments, the electrical components that are configured on the secondary first face part may especially not be SMDs. In embodiments, at most 50%, such as at most 40%, especially at most 20% of the electrical components that are configured on the secondary first face part may be SMDs. Additionally or alternatively, in embodiments, a percentage of SMDs of the total electrical components on the primary first face part (q1) may be higher than a percentage of SMDs of the total electrical components on the secondary first face part (q2). In further embodiments, q1/q2≥1.1, such as q1/q2≥1.5, especially q1/q2≥2. Hence, in specific embodiments the electrical arrangement comprises n electrical components supported by the support, wherein n≥10, wherein during operation of the (light generating) system one or more of the n electrical components at least partly rise in temperature, wherein at least one of the 30% largest in temperature rising electrical components is supported by the primary first face part. In further embodiments the at least one of the 30% largest in temperature rising electrical components is selected from the group of a field-effect transistor, a diode, and a coil. In yet further embodiments, the at least one of the 30% largest in temperature rising electrical components is a surface-mount device. As the primary first face part may be the part of the support that is cooled most efficiently, putting one or more components that generate (relatively) a lot of heat and/or are very sensitive to increased temperatures on the primary first face part may provide the best results.

As indicated above, in embodiments the first top face may comprise a first curvature. As this first curvature may exert a force on the primary second face part in a direction away from the housing bottom, the primary (support) part may be curved or bent. As indicated above, the support may in embodiments be arranged at a distance (h1) from the housing bottom. This distance (h1) may especially refer to the distance between the (second face of the) support and the housing bottom at a part of the support where the support is not curved or bent.

In further embodiments, a plane (P1) may be defined parallel to the housing bottom. Especially, the plane (P1) may be comprised by the interior bottom face of the housing bottom. In embodiments, the second face may, relative to the plane (P1), have a first average height H₁ₐ, averaged over an area A₅₁₂ of the second face. The primary second face part may in embodiments have, relative to the plane (P1) a second average height H₂ₐ, averaged over an area A₅₁₁₁ of the primary second face part. As the first top face may exert a force on the primary (support) part, this may cause the primary (support) part to be configured at a larger first average height compared to an average height of the secondary (support) part. Therefore, the primary (support) part may be configured at a larger first average height compared to the second average height H₂ₐ of the primary second face part of the (total) support. Therefore, in embodiments, 1.01≤H₂ₐ/H₁ₐ≤1.5, such as 1.01≤H₂ₐ/H₁ₐ≤1.2, especially 1.05≤H₂ₐ/H₁ₐ≤1.2. Hence, in specific embodiments relative to a plane (P1) parallel to the housing bottom the second face has a first average height Hla, averaged over an area A₅₁₂, wherein the primary second face part has, relative to the plane (P1) a second average height H₂ₐ, averaged over an area A₅₁₂₁ of the primary second face part, wherein 1.01≤H₂ₐ/H₁ₐ≤1.2.

In embodiments, the primary (support) part may have the same size as the first top face. In alternative embodiments, the primary (support) part may be larger than the first top face. As indicated above, the primary second face part may be configured in physical contact with the first top face. In embodiments, at least 75%, such as at least 80%, especially at least 85%, such as at least 90% of an area A₅₁₂₁ of the primary second face part may be configured in physical contact with the first top face. Hence, in specific embodiments at least 80% of an area A₅₁₂₁ of the primary second face part is configured in physical contact with the first top face. Such a relatively large contact area, herein also indicated as first contact area A_{C1}, may provide good heat dissipation from the primary (support) part.

As indicated above, the first top face may comprise a first curvature with a first curvature radius (r₁). In embodiments, the first curvature radius (r₁) of the first curvature of the first top face may be selected from the range of 0.3*L₁≤r₁≤15*L₁, such as 0.5*L₁≤r₁≤10*L₁, especially 0.6*L₁≤r₁≤5*L₁. Hence, in specific embodiments the first curvature radius (r₁) of the first curvature of the first top face is selected from the range of 0.5*L₁≤r₁≤10*L₁, such as 1*L₁≤r₁≤10*L₁. For smaller values of the first curvature radius (r₁), the contact area (A_{C1}) may be too small for good heat dissipation or the support may even break. For larger values of the first curvature radius (r₁) there may be less tension on the support as a result of which the heat dissipation may be less efficient. In embodiments, the first curvature radius (r₁) may be at least 10 cm, such as at least about 20 cm, like in specific embodiments selected from the range of 40-300 cm.

Here below, thermal aspects are discussed. Material properties, especially heat conductive properties, of the housing and/or the first thermal conduction arrangement part may also contribute to heat dissipation away from the electrical arrangement. Therefore, the housing and/or the first thermal conduction arrangement may comprise materials with a good thermal conductivity, especially thermally conductive materials. As the name suggests, the thermally conductive material may especially be thermally conductive. The thermally conductive material may facilitate conducting heat away from the electrical components. In embodiments, the thermally conductive material may have a thermal conductivity of at least 0.1 W/mK, especially at least 1 W/mK, more especially at least 10 W/mK. In embodiments, the housing bottom may comprise a first thermally conductive material, wherein the first thermally conductive material may comprise e.g. aluminum, though other thermally conductive materials may also be chosen. Additionally or alternatively, the first thermal conduction arrangement part may comprise a second thermally conductive material, wherein the second thermally conductive material may comprise aluminum, though other thermally conductive materials may also be chosen. Hence, in specific embodiments the first thermal conduction arrangement part and/or the housing bottom may comprise a material selected from the group of aluminum and magnesium. In embodiments, the first thermally conductive material and the second thermally conductive material may be the same type of material. In alternative embodiments, the first thermally conductive material and the second thermally conductive material may be different materials. Instead of aluminum, or in addition to aluminum, magnesium may be chosen. Aluminum (or magnesium) may be die cast. However, in embodiments aluminum may also be extruded.

In embodiments, the first thermal conduction arrangement part may comprise a closed chamber. Especially, the closed chamber may in embodiments comprise a closed air chamber. In this way the arrangement may be lighter whilst still maintaining mechanical (and structural) integrity. Less material may be required, which may result in a reduction of costs, while maintaining a good thermal conduction. Hence, in specific embodiments the first thermal conduction arrangement part comprises a closed chamber. Especially, the closed chamber may be a hollow body, e.g. enclosing air.

In further embodiments, the first thermal conduction arrangement part and the housing bottom may be comprised by a monolithic body. Especially, the monolithic body may in embodiments be a deep drawn or injection molded monolithic body. Especially, the first thermal conduction arrangement part and the housing bottom may in embodiments be comprised by an injection molded monolithic body. Hence, in specific embodiments the first thermal conduction arrangement part and the housing bottom are comprised by a monolithic body. In this way, there may be excellent (thermal) contact and thus excellent heat dissipation from the first thermal conduction arrangement part to the housing (bottom). Also, such a monolithic body may be relatively easy to manufacture.

Returning to the second thermal conduction arrangement part, here below some further embodiments are described. As indicated above, the second thermal conduction arrangement part may in embodiments comprise a second bottom face configured in thermal contact with the primary first face part. In further embodiments, 5-80%, such as 10-60%, especially 15-50% of an area (A₅₁₁₁) of the primary first face part may be configured in physical contact with the second bottom face. Hence, in specific embodiments 10-60% of an area (A₅₁₁₁) of the primary first face part is configured in physical contact with the second bottom face. In this way, the second thermal conduction arrangement may especially increase a contact between the primary second face part and the first thermal conduction arrangement part and enhance the heat dissipation.

Hence, the first face may comprise a total first face area, of which part, indicated as “primary first face part”, may comprise the first electrical component, and which part may be bent by the second thermal conduction arrangement part. The total first face area may essentially be A_{S}. This second thermal conduction arrangement part may be in contact with part of the primary first face part; this part of the primary first face part in contact with the second thermal conduction arrangement part may have an area, indicated as contact area (A_{C2}). The area of the primary first face part is indicated as area A₅₁₁₁. Therefore, in embodiments A_{C2}≤A₅₁₁₁<A_{S}.

The first face area, the contact areas, the areas of the secondary first face part and the primary first face part are in general defined as projections on (a plane parallel to) the housing bottom.

The area of the secondary first face part may be indicated as A₅₁₁₂. Hence, in embodiments A_{S}=A₅₁₁₁+A₅₁₁₂. As these areas may refer to projections on (a plane parallel to) the housing bottom, the area of the second face may essentially be the same as the total area of the first face.

As indicated above, the second bottom face may comprise a second curvature with a second curvature radius (r₂). In embodiments, the second curvature radius (r₂) of the second curvature of the second bottom face is selected from the range of 0.3*L₁≤r₂≤15*L₁, such as 0.5*L₁≤r₂≤10*L₁, especially 0.6*L₁≤r₂≤5*L₁. Hence, in specific embodiments the second curvature radius (r₂) of the second curvature of the second bottom face is selected from the range of 0.5*L₁≤r₂≤10*L₁. Similar to values of the first curvature radius (r₁), for smaller values of the second curvature radius (r₂), a (second) contact area (A_{C2}) may be too small for good heat dissipation or the support may even break. For larger values of the second curvature radius (r₂) there may be less tension on the support as a result of which the heat dissipation may be less efficient.

In embodiments, the second bottom face may have an overlap area A_{O2}, wherein the overlap area A_{O2} may be defined as an area of overlapping parts of projections of the second bottom face and the first face of the support on the housing bottom.

In embodiments, the second curvature radius (r₂) may be at least 10 cm, such as at least about 20 cm, like in specific embodiments selected from the range of 40-300 cm.

In embodiments, the second thermal conduction arrangement part may in itself have a relatively low thermal conductivity (e.g. compared to some metals, like aluminum). In such embodiments, the second thermal conduction arrangement part may comprise a material selected from the group of ceramic material and polymeric material. In such embodiments, the heat dissipation may substantially occur via the first thermal conduction arrangement part. In alternative embodiments, the second thermal conduction arrangement part may in itself have a relatively high thermal conductivity. In such embodiments, the second thermal conduction arrangement part may comprise a third thermally conductive material, wherein the third thermally conductive material may comprise aluminum. In this way, heat from the primary (support) part may be dissipated via both the first thermal conduction arrangement part and the second thermal conduction arrangement part. Hence, in specific embodiments the second thermal conduction arrangement part comprises a material selected from the group of aluminum, ceramic material, and polymeric material, though other thermally conductive materials may also be chosen. In further embodiments, the third thermally conductive material may be the same type of material as one or more of the first thermally conductive material and the second thermally conductive material. In alternative embodiments, the third thermally conductive material may differ from the first thermally conductive material and the second thermally conductive material. Instead of aluminum, or in addition to aluminum, magnesium may be chosen. As indicated above, aluminum (or magnesium) may be die cast. However, in embodiments aluminum may also be extruded.

The thermally conductive materials mentioned herein may e.g. aluminum or magnesium, though other thermally conductive materials may also be possible.

A thermally conductive material may especially have a thermal conductivity of at least about 20 W/(m*K), like at least about 30 W/(m*K), such as at least about 100 W/(m*K), like especially at least about 200 W/(m*K). In yet further specific embodiments, a thermally conductive material may especially have a thermal conductivity of at least about 10 W/(m*K). In embodiments, the thermally conductive material may comprise one or more of copper, aluminum, silver, gold, silicon carbide, aluminum nitride, boron nitride, aluminum silicon carbide, beryllium oxide, a silicon carbide composite, aluminum silicon carbide, a copper tungsten alloy, a copper molybdenum carbide, carbon, diamond, and graphite. However, in embodiments also magnesium may be applied. Alternatively, or additionally, the thermally conductive material may comprise or consist of aluminum oxide.

The second thermal conduction arrangement part may have a width (W2) and a length (L2). In embodiments, L2>W2, such as L2≥1.1*W2, especially L2≥1.5*W2. In further embodiments L2≥2*W2, such as L2≥5*W2. In further embodiments, the second thermal conduction arrangement part may comprise a ridge having a length (L3), a width (W3) and a height (H3). The ridge may in embodiments be configured perpendicular to the second bottom face of the second thermal conduction arrangement. In embodiments, the ridge length (L3) may be parallel to the second thermal conduction arrangement length (L2). In further embodiments, the ridge width (W3) may be (substantially) parallel to the second thermal conduction arrangement width (W2). In embodiments, W3<W2, such as W3≤0.95*W2, especially W3≤0.9*W2. In further embodiments, W3≤0.75*W2, especially W3≤0.5*W2, such as 0.05*W2≤W3≤0.4*W2. Additionally or alternatively, in embodiments L3≤L2, such as L3≤0.95*L2, especially L3≤0.9*L2. In further embodiments, L3≤0.75*L2, especially L3≤0.5*L2. In further embodiments, H3≥0.15*W2, such as H3≥0.25*W2, especially H3≥0.4*W2. The second thermal conduction arrangement part may in further embodiments comprise (at least) two ridges. Hence, in specific embodiments the second thermal conduction arrangement part has a width (W2) and a length (L2), wherein L2>W2; wherein the second thermal conduction arrangement part comprises a ridge having a width (W3) and a height (H3), wherein W3<W2, and wherein H3≥0.25*W2. Yet, in embodiments, 1.5*W2≤L2≤20*W2, such as 5*W2≤L2≤15*W2. Yet, in embodiments H3≤1.5*W2, such as H3≤W2. In further embodiments, the ridge may have a cross-sectional shape of an L or of an T. The ridge may in embodiments comprise the third thermally conductive material. In alternative embodiments, the ridge may in embodiments comprise a material that differs from the material of the second bottom face. In yet other embodiments, the second thermal conduction arrangement part may comprise multiple ridges, such as 2-6 ridges, though more may also be possible.

In embodiments wherein the first top face comprises a first curvature, the first thermal conduction arrangement part may thus be convex. In embodiments wherein the thermal conduction arrangement comprises a second thermal conduction arrangement part comprising a bottom face comprising the second curvature, the first thermal conduction arrangement part may be planar or may be concave. In the latter embodiments, the curvature may essentially be parallel to the curvature of the bottom face, or the radius of the convex first thermal conduction arrangement part may have a larger radius than the second curvature radius. Especially, however, in embodiments wherein the thermal conduction arrangement comprises a second thermal conduction arrangement part comprising a bottom face comprising the second curvature, the first thermal conduction arrangement part may essentially be planar.

The arrangement as described herein may be part of different types of systems, such as part of a light generating system. In embodiments, the arrangement may be configured as a driver. Especially, the arrangement may in embodiments be configured as a driver for the (light generating) system. The light generating system may in embodiments further comprise a system housing. Especially, the arrangement may in embodiments be enclosed by the system housing. In further embodiments, the support may comprise a printed circuit board. Hence, in specific embodiments the arrangement is configured as a driver, wherein the light generating system comprises a system housing, wherein the arrangement is enclosed by the system housing; and wherein the support comprises a printed circuit board. The light generating system may comprise one or more light generating devices. The one or more light generating devices may be controlled by the driver. The light generating device may in embodiments comprise one or more solid state light sources. The light generating system may be configured to generate system light. The system light may comprise device light of the one or more light generating devices. In embodiments, the system light may be white light. In other embodiments, the system light may be colored light. In yet other embodiments, the spectral power distribution of the system light may be controllable (such as using the driver).

The light generating system may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, (outdoor) road lighting systems, urban lighting systems, green house lighting systems, horticulture lighting, digital projection, or LCD backlighting. The light generating system (or luminaire) may be part of or may be applied in e.g. optical communication systems or disinfection systems.

The term “controlling” and similar terms especially refer at least to determining the behavior or supervising the running of an element. Hence, herein “controlling” and similar terms may e.g. refer to imposing behavior to the element (determining the behavior or supervising the running of an element), etc., such as e.g.

measuring, displaying, actuating, opening, shifting, changing temperature, etc.. Beyond that, the term “controlling” and similar terms may additionally include monitoring. Hence, the term “controlling” and similar terms may include imposing behavior on an element and also imposing behavior on an element and monitoring the element. The controlling of the element can be done with a control system, which may also be indicated as “controller”. The control system and the element may thus at least temporarily, or permanently, functionally be coupled. The element may comprise the control system. In embodiments, the control system and element may not be physically coupled. Control can be done via wired and/or wireless control. The term “control system” may also refer to a plurality of different control systems, which especially are functionally coupled, and of which e.g. one control system may be a master control system and one or more others may be slave control systems. A control system may comprise or may be functionally coupled to a user interface.

The control system may also be configured to receive and execute instructions from a remote control. In embodiments, the control system may be controlled via an App on a device, such as a portable device, like a Smartphone or I-phone, a tablet, etc .. The device is thus not necessarily coupled to the lighting system, but may be (temporarily) functionally coupled to the lighting system.

Hence, in embodiments the control system may (also) be configured to be controlled by an App on a remote device. In such embodiments the control system of the lighting system may be a slave control system or control in a slave mode. For instance, the lighting system may be identifiable with a code, especially a unique code for the respective lighting system. The control system of the lighting system may be configured to be controlled by an external control system which has access to the lighting system on the basis of knowledge (input by a user interface of with an optical sensor (e.g. QR code reader) of the (unique) code. The lighting system may also comprise means for communicating with other systems or devices, such as on the basis of Bluetooth, Thread, WIFI, LiFi, ZigBee, BLE or WiMAX, or another wireless technology.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

However, in embodiments a control system may be available, that is adapted to provide at least the controlling mode. Would other modes be available, the choice of such modes may especially be executed via a user interface, though other options, like executing a mode in dependence of a sensor signal or a (time) scheme, may also be possible. The operation mode may in embodiments also refer to a system, or apparatus, or device, that can only operate in a single operation mode (i.e. “on”, without further tunability).

Hence, in embodiments, the control system may control in dependence of one or more of an input signal of a user interface, a sensor signal (of a sensor), and a timer. The term “timer” may refer to a clock and/or a predetermined time scheme.

In a further aspect, the invention also provides the arrangement as such.

In yet a further aspect, the invention also provides a lamp or a luminaire comprising the light generating system as defined herein. The luminaire may further comprise a housing, optical elements, louvres, etc. etc. The lamp or luminaire may further comprise a housing enclosing the light generating system. The lamp or luminaire may comprise a light window in the housing or a housing opening, through which the system light may escape from the housing. In yet a further aspect, the invention also provides a projection device comprising the light generating system as defined herein. Especially, a projection device or “projector” or “image projector” may be an optical device that projects an image (or moving images) onto a surface, such as e.g. a projection screen. The projection device may include one or more light generating systems such as described herein. Hence, in an aspect the invention also provides a lighting device selected from the group of a lamp, a luminaire, a projector device, a disinfection device, a photochemical reactor, an automotive lighting device and an optical wireless communication device, comprising the light generating system as defined herein. The lighting device may comprise a housing or a carrier, configured to house or support, one or more elements of the light generating system. For instance, in embodiments the lighting device may comprise a housing or a carrier, configured to house or support the (light generating) system.

The terms “light” and “radiation” are herein interchangeably used, unless clear from the context that the term “light” only refers to visible light. The terms “light” and “radiation” may thus refer to UV radiation, visible light, and IR radiation. In specific embodiments, especially for lighting applications, the terms “light” and “radiation” refer to visible light.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIGS. 1a-c schematically depict embodiments of the invention.

FIGS. 2a-d schematically depict further embodiments of the invention.

FIG. 3 schematically depicts an embodiment of projected surface areas of the invention.

FIGS. 4 and 5 schematically depict applications of the invention.

The schematic drawings are not necessarily to scale.

### DETAILED DESCRIPTION OF THE EMBODIMENTS

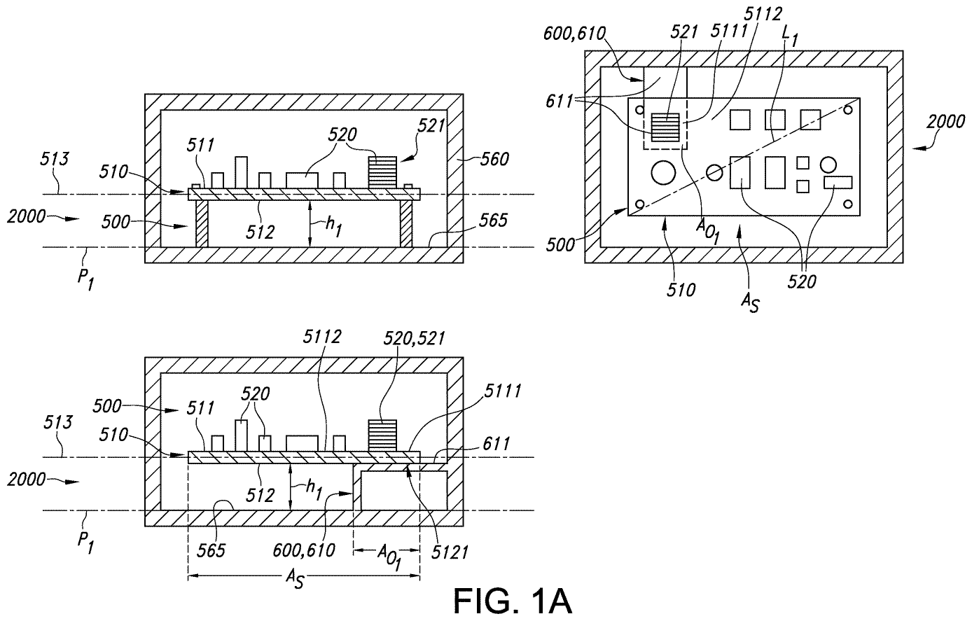

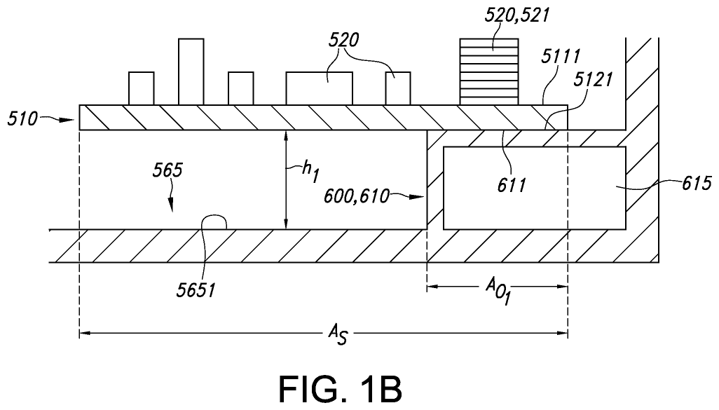

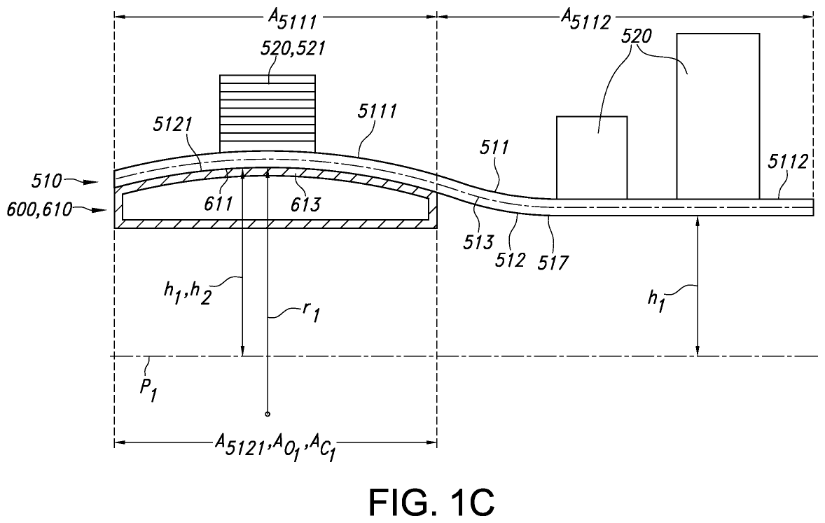

FIG. 1a schematically depicts cross-sections (left) and a top view (right) of an arrangement 2000 (to be comprised by a system 1000, not depicted here), wherein the arrangement 2000 comprises an electrical arrangement 500, a housing 560, and a thermal conduction arrangement 600. The housing 560 comprises a housing bottom 565. As depicted, the electrical arrangement 500 may especially be configured in the housing 560. The electrical arrangement may in embodiments comprise a support 510 and a plurality of electrical components 520 supported by the support 510. The support 510 comprises a first face 511, a second face 512, largest dimension (especially a diameter or diagonal) L₁ (in the support cross-sectional plane 513, see below). The support 510 (especially the second face 512) is arranged at a distance h1 from the housing bottom 565. In embodiments, the first face 511 comprises a primary first face part 5111. In embodiments, at least a first electrical component 521 (which during operation generates heat) is mechanically and/or electrically coupled to the primary first face part 5111. In further embodiments, a plurality of (other) electrical components 520 are mechanically and/or electrically coupled to a secondary first face part 5112. The second face 512 comprises a primary second face part 5121, configured opposite of the primary first face part 5111. The thermal conduction arrangement 600 may in embodiments comprise a first thermal conduction arrangement part 610, configured in thermal contact with the housing bottom 565 or at least partly comprised by the housing bottom 565. The first thermal conduction arrangement part 610 comprises a first top face 611. In embodiments, the first top face may be configured in thermal contact with the primary second face part 5121.

Herein, in some cross-sectional views, for explanation purposes, also areas are indicated. Hence, in FIG. 1A, the cross-sectional area As is indicated, which has the indicated width, and is an area of a face perpendicular to the plane of drawing.

Especially, the electrical arrangement 500 may in embodiments comprise n electrical components 520 supported by the support 510. In embodiments at least one of the 30% largest in temperature rising electrical components 520 may be selected from the group of a field-effect transistor, a diode, and a coil. In embodiments n≥10. During operation of the (light generating) system 1000, one or more of the n electrical components 520 may in embodiments at least partly rise in temperature. In embodiments, at least one of the 30% largest in temperature rising electrical components 520 may be supported by the primary first face part 5111. Especially, the at least one of the 30% largest in temperature rising electrical components 520 may in embodiments be a surface-mount device. In further embodiments, at least 50% of all electrical components 520 may be mechanically and/or electrically coupled to the secondary first face part 5112.

FIG. 1b schematically depicts an embodiment wherein the first top face 611 has an overlap area A_{O1}, defined as an area of overlapping parts of projections of the first top face 611 and the second face 512 on the housing bottom 565. In embodiments 0.05≤A_{O1}/Aₛ≤0.33. Herein, Aₛ indicates a support cross-sectional area. Thus, the second face 512 and the first top face 611 may have a local (additional) contact. In the depicted embodiment, the first thermal conduction arrangement part 610 comprises a closed (air) chamber 615. In further embodiments, the first thermal conduction arrangement part 610 and the housing bottom 565 may be comprised by a monolithic body. In embodiments, the monolithic body may be a deep drawn or injection molded monolithic body.

FIG. 1c schematically depicts the support cross-sectional plane 513 configured parallel to the first face 511 (and the second face 512). FIG. 1c also depicts an embodiment wherein the first (thermal conduction arrangement) top face 611 comprises a first curvature 613 with a first curvature radius r₁. In embodiments r₁≥0.5*L₁. In further embodiments the first curvature radius r₁ of the first curvature 613 of the first top face 611 may be selected from the range of 0.5*L₁≤r₁≤10*L₁. Especially, the first curvature 613 may in such embodiments exert a force on the primary second face part 5121 in a direction away from the housing bottom 565. FIG. 1c also depicts a plane P1 parallel to the housing bottom 565 (and comprised by an interior bottom face 5651 of the housing bottom 565). In embodiments, the first face 511 has, relative to plane P1, a first average height H₁ₐ, averaged over an area A₅₁₁. In general, the first average height H₁ₐ, or thickness may essentially be constant. Similarly, the primary first face part 5111 in embodiments has, relative to the plane P1, a second average height H₂ₐ, averaged over an area A₅₁₁₁ of the primary first face part 5111. In embodiments 1.01≤H₂ₐ/H₁ₐ≤1.2. (N. B. the average heights H₁ₐ and H₂ₐ are not depicted because they are average values.) Next to the first thermal conduction arrangement part 610, the support 510 may also be a bit elevated.

Note that the embodiment of FIG. 1c may have a relatively large first contact area A_{C1}, as a substantial part of the area of the first top face may be in contact with a substantial part of the (area A₅₁₂₁ of the) primary second face part 5121.

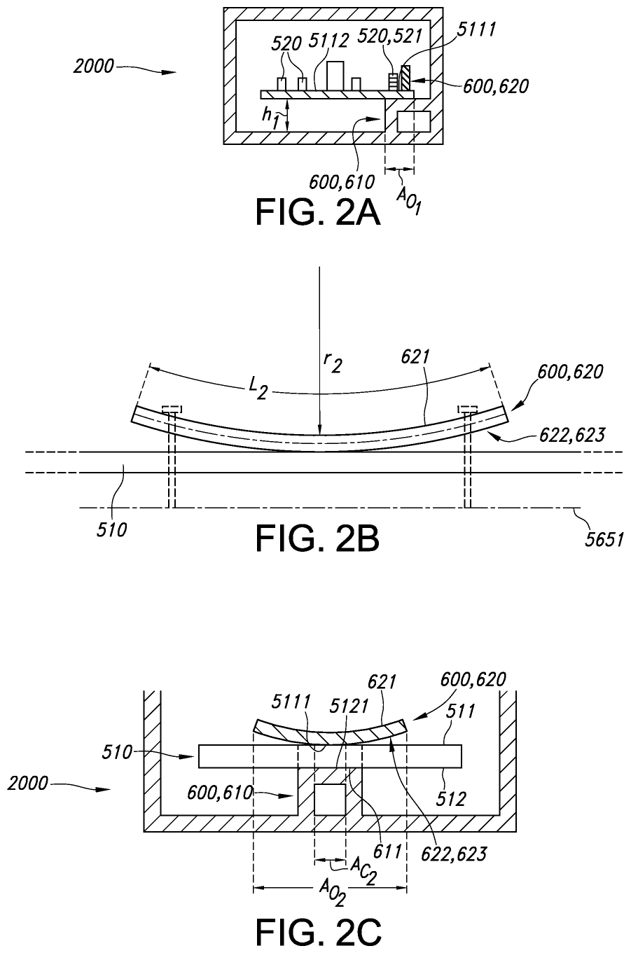

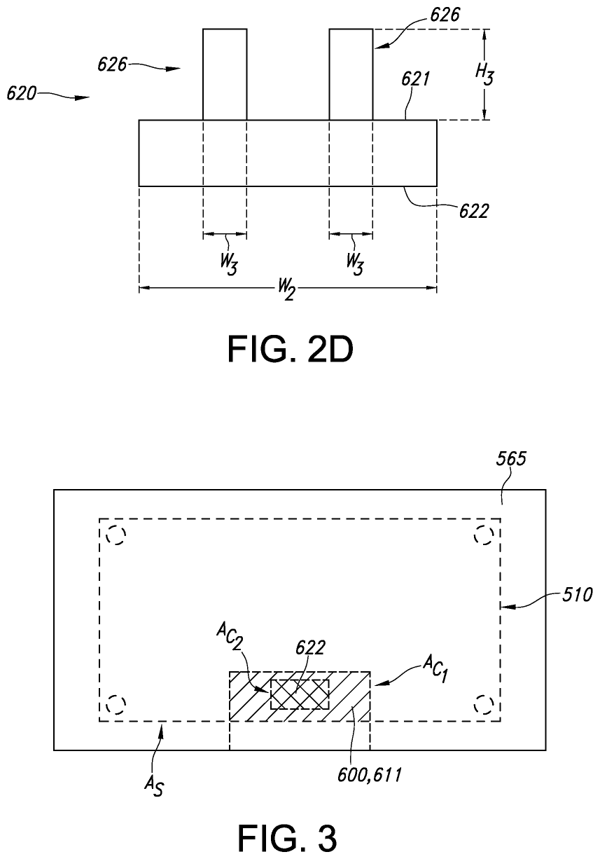

FIG. 2a schematically depicts a cross-section of an arrangement 2000 (to be comprised by a system 1000, not depicted here). In the depicted arrangement 2000, the thermal conduction arrangement 600 further comprises a second thermal conduction arrangement part 620. The second thermal conduction arrangement part 620 may especially be configured in thermal contact with the primary first face part 5111.

FIG. 2b schematically depicts embodiments wherein the thermal conduction arrangement 600 comprises a second thermal conduction arrangement part 620. Reference 5651 indicates an interior bottom face of the housing bottom 565. The second thermal conduction arrangement part 620 comprises a second (thermal conduction arrangement) bottom face 622. In embodiments, the second bottom face 622 may be configured in thermal contact with the primary first face part 5111. Especially, the second bottom face 622 may in embodiments comprise a second curvature 623 with a second curvature radius r₂. In embodiments r₂≥0.5*L₁. In further embodiments the second curvature radius r₂ of the second curvature 623 of the second bottom face 622 may be selected from the range of 0.5*L₁≤r₂≤10*L₁. Especially, the second curvature 623 may in embodiments locally exert a force on the primary first face part 5111 in a direction of the first top face 611 as schematically depicted in FIG. 2c.

FIG. 2d schematically depicts the second thermal conduction arrangement part 620 having a width W2 and a length L2 (depicted in FIG. 2b). In embodiments L2>W2. In embodiments the second thermal conduction arrangement part 620 may comprise a ridge 626 having a width W3 and a height H3. In embodiments W3<W2. In further embodiments H3≥0.25*W2.

FIG. 3 schematically depicts projections on the housing bottom 565. Especially, projections of the support 510, first top face 611 and second bottom face 622 are depicted. In embodiments at least 80% of an area A₅₁₂₁ of the primary second face part 5121 is configured in physical contact with the first top face 611. This contact area, when projected on the bottom 565, may be indicated with A_{C1}. In embodiments 10-60% of an area A₅₁₁₁ of the primary first face part 5111 may be configured in physical contact with the second bottom face 622. This contact area, when projected on the bottom 565, may be indicated with A_{C2}.

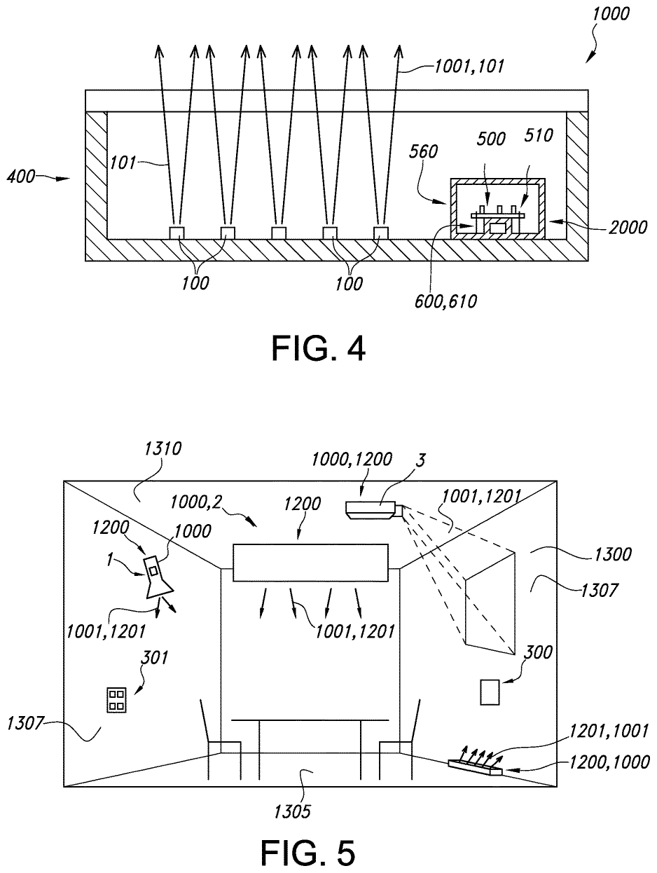

FIG. 4 schematically depicts an embodiment wherein the system 1000 comprises a light generating system. The light generating system 1000 may comprise one or more light generating devices 100. The one or more light generating devices 100 may be configured to provide device light 101. Further, the light generating system 1000 may in an operational mode provide system light 1001. In embodiments, the arrangement 2000 may be configured as a driver (for the light generating system 1000). In the depicted embodiment, the light generating system 1000 comprises a system housing 400. Especially, the arrangement 2000 may be enclosed by the system housing 400. In specific embodiments, the support 510 may comprise a printed circuit board.

FIG. 5 schematically depicts an embodiment of a luminaire 2 comprising the light generating system 1000 as described above. Reference 301 indicates a user interface which may be functionally coupled with the control system 300 comprised by or functionally coupled to the light generating system 1000. FIG. 5 also schematically depicts an embodiment of lamp 1 comprising the light generating system 1000. Reference 3 indicates a projector device or projector system, which may be used to project images, such as at a wall, which may also comprise the light generating system 1000. Hence, FIG. 5 schematically depicts embodiments of a lighting device 1200 selected from the group of a lamp 1, a luminaire 2, a projector device 3, a disinfection device, a photochemical reactor, an automotive lighting device, and an optical wireless communication device, comprising the light generating system 1000 as described herein. In embodiments, such lighting device may be a lamp 1, a luminaire 2, a projector device 3, a disinfection device, or an optical wireless communication device. Lighting device light escaping from the lighting device 1200 is indicated with reference 1201. Lighting device light 1201 may essentially consist of system light 1001, and may in specific embodiments thus be system light 1001. Reference 1300 refers to a space, such as a room. Reference 1305 refers to a floor and reference 1310 to a ceiling; reference 1307 refers to a wall.

Newly developed drivers, such as for stadium lighting, may have high power output (such as up to 1800 W). The cooling of such high power drivers gets more difficult, especially cooling relative small components with high power losses. Cooling of components in high power drivers is complex. Only screwing of the support (especially a PCB) in the housing is mostly not sufficient. Therefore one or more of extra (large) heat sinks, thermal interphase material and complex constructions are often used. Currently, in high power drivers, extra (large) heat sinks are often used for cooling. Also gap pads or thermal grease are often used to make thermal contact between the drivers and the heat sinks. However, thermal conductive pads may be non-recyclable, heavy, and expensive. Using extra (large) heat sinks and thermal interface materials is complex and expensive.

The present invention uses the (aluminum) housing for cooling. Thermal contact between the drivers and the housing may be secured with curved surfaces. In embodiments, the housing may comprise a curved surface. In this part of the invention, the contact surfaces in the (aluminum) housing may be curved to secure the thermal contact between the support and the housing. The PCB may be slightly bent after screwing, so there is pressure on the PCBA to secure the thermal contact.

Additionally or alternatively, thermal contact may be secured with (plastic or metal) springs. In embodiments, the spring is bent (or has a curved surface). After mounting, the spring may be flat, so there is pressure on the support to secure the thermal contact. First measurements show a decrease of around 10°C on the critical components when the springs are used. Especially no extra heat sinks or thermal interphase material is needed.

The term “plurality” refers to two or more.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%.

The term “comprise” also includes embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

Hence, amongst others the invention provides a light generating system 1000 comprising an arrangement 2000, wherein the arrangement 2000 comprises an electrical arrangement 500, a housing 560, and a thermal conduction arrangement 600, wherein the thermal conduction arrangement comprises a curved surface exerting a force on part of the electrical arrangement. Yet, the invention also provides the arrangement 2000 as such.

1. A light generating system comprising an arrangement, wherein the arrangement comprises an electrical arrangement, a housing, and a thermal conduction arrangement, wherein:
the housing comprises a housing bottom;
the electrical arrangement, configured in the housing, comprises a support and a plurality of electrical components supported by the support; the support comprises a first face, a second face, a support cross-sectional plane configured parallel to the first face, a support cross-sectional area As, and a largest dimension (L1) in the support cross-sectional plane; wherein the support is arranged at a distance (h1) from the housing bottom; wherein the first face comprises a primary first face part, wherein at least a first electrical component is mechanically and/or electrically coupled to the primary first face part; wherein the second face comprises a primary second face part, configured opposite of the primary first face part;
the thermal conduction arrangement comprises a first thermal conduction arrangement part, configured in thermal contact with the housing bottom or at least partly comprised by the housing bottom; wherein the first thermal conduction arrangement part comprises a first top face configured in thermal contact with the primary second face part; wherein the first top face-has an overlap area AO1, defined as an area of overlapping parts of projections of the first top face and the second face on the housing bottom, wherein 0.05≤AO1/As≤0.33; and wherein one or more of the following applies:
(i) the first top face comprises a first curvature with a first curvature radius (r1), wherein r1≥0.5*L1; wherein the first curvature exerts a force on the primary second face part in a direction away from the housing bottom; and
(ii) the thermal conduction arrangement comprises a second thermal conduction arrangement part, wherein the second thermal conduction arrangement part comprises a second bottom face configured in thermal contact with the primary first face part; wherein the second bottom face comprises a second curvature with a second curvature radius (r2), wherein r2≥0.5*L1; wherein the second curvature locally exerts a force on the primary first face part in a direction of the first top face.

2. The light generating system according to claim 1, wherein the electrical arrangement comprises n electrical components supported by the support wherein n≥10, wherein during operation of the light generating system one or more of the n electrical components at least partly rise in temperature, wherein at least one of the 30% largest in temperature rising electrical components is supported by the primary first face part and wherein at least 50% of all electrical components is mechanically and/or electrically coupled to a secondary first face part.

3. The light generating system according to claim 2, wherein one or more of the following applies: (i) the at least one of the 30% largest in temperature rising electrical components is selected from the group of a field-effect transistor, a diode, and a transformer, and (ii) the at least one of the 30% largest in temperature rising electrical components is a surface-mount device.

4. The light generating system according to claim 1, wherein relative to a plane (P1) parallel to the housing bottom the second face has a first average height H1a, averaged over an area A512, wherein the primary second face part has, relative to the plane (P1) a second average height H2a, averaged over an area A5121 of the primary second face part, wherein 1.01≤H2a/H1a≤1.2.

5. The light generating system according to claim 1, wherein at least 80% of an area A5121 of the primary second face part is configured in physical contact with the first top face.

6. The light generating system according to claim 1, wherein the first curvature radius (r1) of the first curvature of the first top face is selected from the range of 0.5*L1≤r1≤15*L1.

7. The light generating system according to claim 1, wherein the first thermal conduction arrangement part and/or the housing bottom comprise a material selected from the group of aluminum and magnesium.

8. The light generating system according to claim 1, wherein the first thermal conduction arrangement part comprises a closed chamber.

9. The light generating system according to claim 1, wherein the first thermal conduction arrangement part and the housing bottom are comprised by a monolithic body.

10. The light generating system according to claim 1, wherein 10-60% of an area A5111 of the primary first face part is configured in physical contact with the second bottom face.

11. The light generating system according to claim 1, wherein the second curvature radius (r2) of the second curvature of the second bottom face is selected from the range of 0.5*L1≤r2≤10*L1.

12. The light generating system according to claim 1, wherein the second thermal conduction arrangement part comprises a material selected from the group of aluminum, magnesium, ceramic material, and polymeric material.

13. The light generating system according to claim 1, wherein the second thermal conduction arrangement part has a width (W2) and a length (L2), wherein L2>W2; wherein the second thermal conduction arrangement part comprises a ridge having a width (W3) and a height (H3), wherein W3<W2, and wherein H3≥0.25*W2.

14. The light generating system according to claim 1, wherein the arrangement is configured as a driver; and wherein the light generating system comprises a system housing, wherein the arrangement is enclosed by the system housing; and wherein the support comprises a printed circuit board.

15. A lighting device selected from the group of a lamp, a luminaire, a projector device a disinfection device, a photochemical reactor, an automotive lighting device, and an optical wireless communication device, comprising the light generating system according to claim 1.
